(19) United States
(12) Patent Application Publication
(10) Pub. No.: US 2025/0308961 A1
(43) Pub. Date: Oct. 2, 2025

(54) APPARATUS FOR DETECTING INTERNAL POSITIONS OF A CHAMBER IN A WAFER PROCESSING SYSTEM

(71) Applicant: ASM IP Holding B.V., Almere (NL)

(72) Inventor: Kenji Mizusawa, Tokyo (JP)

(21) Appl. No.: 19/092,088

(22) Filed: Mar. 27, 2025

Related U.S. Application Data
(60) Provisional application No. 63/571,780, filed on Mar. 29, 2024.

(51) Int. Cl. H01L 21/67

(52) U.S. Cl. CPC H01L 21/67259; H01L 21/67126

(57) ABSTRACT

An object detection apparatus used to detect objects in a chamber of a wafer processing system is presented. The apparatus for detecting object positions in a chamber of a wafer processing system comprises: a body frame comprising a sensing part and an indicating part, wherein the sensing part comprises at least one sensor for sensing positions of objects in a chamber and the indicating part comprises at least one signal for indicating detection of the objects, wherein each of the at least one sensor correspond to each of the at least one signal, and a power unit disposed in the body frame and configured to supply power to the at least one signal. With this apparatus, work such as teaching can be done without opening the chamber or lowering the temperature of the chamber so it is possible to significantly shorten the work time and save energy.

### CROSS-REFERENCE TO RELATED APPLICATION(S)

This application claims the benefit of U.S. Provisional Application 63/571,780 filed on Mar. 29, 2024, the entire contents of which are incorporated herein by reference.

### FIELD OF INVENTION

The present disclosure relates generally to an apparatus which can be placed at an end effector of a wafer processing chamber, More particularly, exemplary embodiments of the present disclosure relate to a position detection apparatus which can detect the insides of a chamber in a wafer processing apparatus for transporting a substrate and a substrate processing apparatus including the end effector.

### BACKGROUND OF THE DISCLOSURE

Currently, most of the equipment & apparatuses used for processing wafers in semiconductor industries make use of high temperature for processing wafers and the consistent temperature is important in that the wafer quality may be decided by the temperature of the wafer.

So, it may be important to hold the heat in the chamber to itself and do not lose it. Once the chamber loses the heat (i.e., temperature drops down) it would take much time to recover to the previous temperature.

Therefore, by doing a work without opening the chamber or lowering the temperature, it is possible to significantly decrease time to take. The present disclosure presents an apparatus that detects the position of parts in the chamber that are invisible or take time to open and see in real.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, an apparatus for detecting object positions in a chamber of a wafer processing system, comprises: a body frame comprising a sensing part and an indicating part, wherein the sensing part comprises at least one sensor for sensing positions of objects in a chamber and the indicating part comprises at least one signal for indicating detection of the objects, wherein each of the at least one sensor correspond to each of the at least one signal, and a power unit disposed in the body frame and configured to supply power to the at least one signal.

In an aspect, the body frame further comprising: a linking part configured to connect the sensing part and the indicating part.

In an aspect, the body frame further comprising at least one concave groove line disposed on one side of the body frame and configured to attach the body frame to an end effector of a robot arm.

In an aspect, the at least one sensor is optical sensor or mechanical push switch.

In an aspect, the at least one signal is LED.

In an aspect, each of the at least one sensor further comprising: a sealing lid configured to seal the sensor from an environment in the chamber.

In accordance with another embodiment there may be provided, an apparatus for detecting object positions in a chamber of a wafer processing system, comprises: a body frame comprising a sensing part and an indicating part, wherein the sensing part comprises a plurality of sensors for sensing positions of objects in a chamber and the indicating part comprises a plurality of signals for indicating detection of the objects, wherein each of the plurality of sensors connected to each of the plurality of signals respectively and when an object is detected by a first sensor, a first signal connected to the first sensor is configured to be lit to show the location of that detection, a processor disposed inside of the body frame and connected to each of the plurality of sensors, and configured to compute the locations of sensed objects in the chamber, and a power unit disposed in the body frame and configured to supply power to the plurality of signals.

In an aspect, the body frame further comprising: a linking part configured to connect the sensing part and the indicating part.

In an aspect, the body frame further comprising at least one concave groove line disposed on one side of the body frame and configured to attach the body frame to an end effector of a robot arm.

In an aspect, the plurality of sensors is one of the optical sensor or mechanical push switch, and wherein the plurality of signals is LED.

In an aspect, each of the plurality of sensors further comprising: a sealing lid configured to seal the sensor from an environment in the chamber.

In accordance with another embodiment there may be provided, an apparatus for detecting object positions in a chamber of a wafer processing system, comprises: a body frame comprising a sensing part and an indicating part, wherein the sensing part comprises a plurality of sensors for sensing positions of objects in a chamber and the indicating part comprises a plurality of signals for indicating detection of the objects, wherein each of the plurality of sensors connected to each of the plurality of signals respectively and when an object is detected by a first sensor, a first signal connected to the first sensor is configured to be lit to show the location of that detection; a communication unit disposed inside of the body frame and connected to the plurality of sensors, the communication unit configured to send out location information of the sensed objects, and a power unit disposed in the body frame and configured to supply power to the plurality of signals.

In another aspect, the apparatus further comprising: a processor disposed inside of the body frame and connected to each of the plurality of sensors and configured to compute the locations of sensed objects in the chamber.

In another aspect, the body frame further comprising: a linking part configured to connect the sensing part and the indicating part.

In another aspect, the body frame further comprising: at least one concave groove line disposed on lower side of the body frame and configured to attach the body frame to an end effector of a robot arm.

In another aspect, the plurality of sensors is one of optical sensor or mechanical push switch.

In another aspect, wherein the plurality of signals is LED.

In another aspect, each of the plurality of sensors further comprising: a sealing lid configured to seal the sensor from an environment in the chamber.

In another aspect, the processor further comprises a memory for saving data.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a general view of an object detection apparatus mounted and attached to an end effector according to an embodiment of the present disclosure.

FIG. 2(a) illustrates a front view of the apparatus seen from the arrow A in FIG. 1 according to an embodiment of the present disclosure.

FIG. 2(b) illustrates a side view of the apparatus seen from the arrow B in FIG. 1 according to an embodiment of the present disclosure.

FIG. 3 illustrates another mode of an object detection apparatus according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers, Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof,

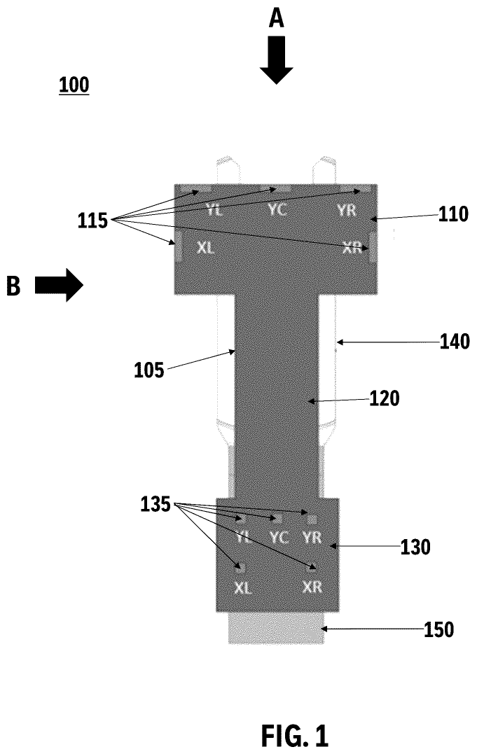

FIG. 1 illustrates a top view of an object detection apparatus according to an embodiment of the present disclosure.

The object detection apparatus 100 may comprise a body frame 105. The body frame 105 may comprise a sensing part 110 and an indicating part 130. In some occasions, the body frame 105 may also comprise a linking part 120 which may connect the sensing part 110 and the indicating part 130. The shape of the apparatus 100 may vary but the thickness may not exceed much than the thickness of an end effector 140 it is mounted on and attached to.

Usually, the thickness of the end effector would be 4˜5 mm therefore the thickness of this apparatus 100 should not exceed 2 or 3 times that of the end effector 140. This limit would be preset by operator or anyone before operating this apparatus 100.

In the sensing part 110, more than one sensors 115 may be positioned in the front and side of the apparatus 100 as illustrated in FIG. 1. The number of sensors may vary due to the system and environment. 5 sensors are shown as an example in FIG. 1. The 5 sensors may be positioned YC (Y axis center), YL (Y axis left), YR (Y axis right), XL (X axis left) and XR (X axis right) and named as such. In the indicating part 130, 5 signals (135) are positioned, and this number of signals is identical to that of the sensors. Each sensor and signal with the same name (YC, YL, YR, X L, XR) may be connected with each other so that for example, when sensor YC may sense an object while moving around while mounted on the end effector 140, then signal YC would be lit so that sensor YC sensed something during the movement can be known to the operator or any personnel or this information (sensed object location information) would be saved onto a unit (not drawn) inside of the apparatus 100 or outside of it (by wireless data transmission).

The apparatus 100 may be mounted on and attached to an end effector 140 but the length of this apparatus 100 and the end effector 140 would suggest that this apparatus 100 would also be mounted on a robot arm 150.

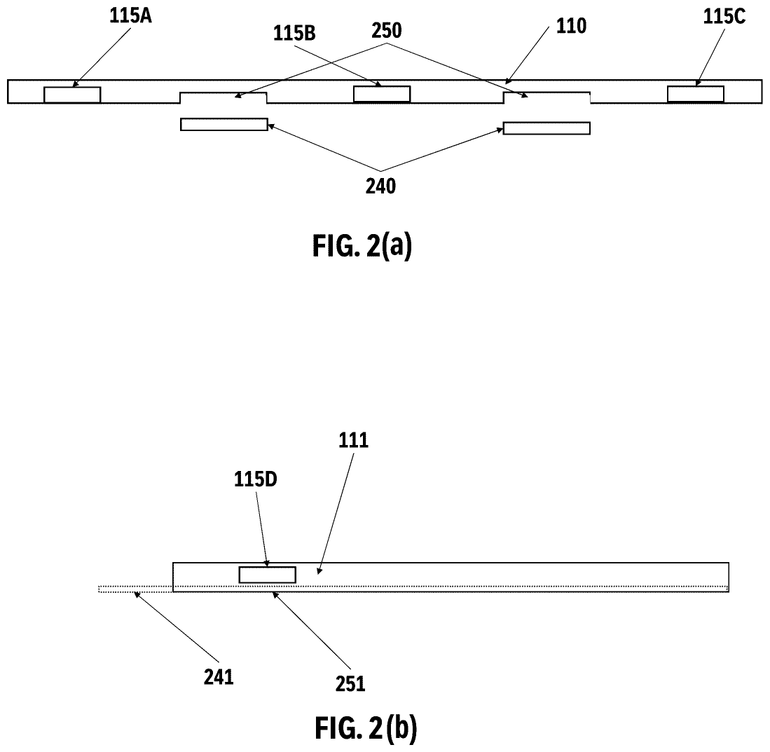

FIG. 2(a) illustrates a frontal view of the apparatus 100 in FIG. 1 (Arrow A direction)

The apparatus 100 may look like FIG. 2(a) when seen from Arrow A direction.

The sensing part 110 may comprise sensors (115A, 11513, 115C) placed in the front side. The body frame (sensing part 110 in this figure) may comprise more than one concave groove lines 250. In FIG. 2(a), there are 2 groove lines 250 since the end effector 240 has 2 blades and the number of groove lines would vary according to the number of the end effector blades.

When the apparatus 100 may be mounted on the end effector 240 as shown in FIG. 2(a), the blades 240 may fit into the concave shaped groove lines 250. The fit may be tight enough so that it may endure the end effector (also the apparatus) moving within the chamber.

FIG. 2(b) illustrates a side view of the apparatus 100 in arrow 13 direction.

From the side, a sensor 115D may be seen at the side of the sensing part 111 and one of the end effectors 241 is also illustrated. Though not visible in this angle, already explained concave groove line 251 may be there to hold the end effector 241 tightly.

The sensors 115, 115A˜115D may be any sensing utility including optical sensor. However, temperature may go up so much in wafer processing environment, and optical sensor may not function well in high temperature environment. Therefore, mechanical pressure switch may also be used in this embodiment. This pressure switch turns on while pressed and when the pressure is removed then it gets turned off.

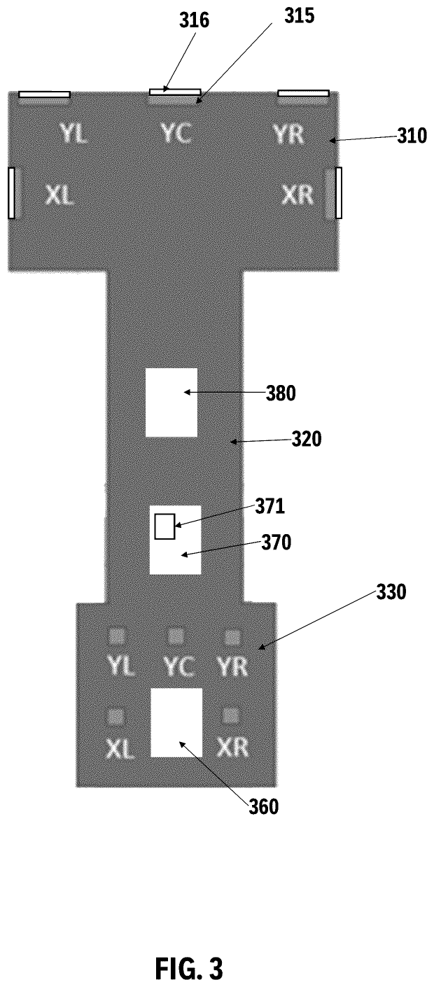

In real environment, it may not be good for the sensors 115, 115A˜115D to be exposed to the harsh (high temperature, plasma, vacuum) conditions so additional sealing may be used to protect the sensors. In FIG. 3, a sensor 315 is shown and a sealing lid 316 for the sensor 315 is also illustrated. Other sensors also have similar sealing setup.

The signals 135 may be simple LEDs so that for example, when a sensor (YC) is turned on, the corresponding signal (YC) is lit during the sensor (YC)'s turn-on period.

The power for sensor and/or signal functions may be equipped inside of the apparatus 100. In FIG. 3, the power 360 may be inside of the indicating part 330 but it may be in the linking part 320 or the sensing part 310 also. Any electric lines and/or wires may be installed inside of the apparatus 100 so that there would be no wires dangling from the apparatus 100.

Usually, an operator and/or user may have to monitor the movement of the end effector 140 along with the apparatus 100 to see if any LED lights would be lit during the movement. However, if a processor 370 may be installed to monitor the locations of sensor turn-ons, the resulting objects in the chamber would be drawn or dotted/printed out from the processor so that constant monitoring by human presence may not be needed.

The processor 370 may be any computing device such as micro-processor, CPU, GPU etc. This processor 370 may comprise a memory 371 along with it. The only restriction may be that it has to be small enough to be equipped inside of the apparatus 100.

In other circumstances, the detected object data (such as position information, the information where the object was met by the apparatus 100) may be transmitted to the outside for review and/or save. This means that a communication unit 380 may be equipped inside of the apparatus 100. It may be better to use the processor 370 or the communication unit 380 mutually exclusively but both may be equipped and used for some applications.

The power 360 may be anything such as secondary batteries, rechargeable batteries, or general batteries.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. An apparatus for detecting object positions in a chamber of a wafer processing system, comprises:
a body frame comprising a sensing part and an indicating part, wherein the sensing part comprises at least one sensor for sensing positions of objects in a chamber and the indicating part comprises at least one signal for indicating detection of the objects, wherein each of the at least one sensor correspond to each of the at least one signal, and
a power unit disposed in the body frame and configured to supply power to the at least one signal.

2. The apparatus according to the claim 1, the body frame further comprising:
a linking part configured to connect the sensing part and the indicating part.

3. The apparatus according to the claim 1, the body frame further comprising:
at least one concave groove line disposed on one side of the body frame and configured to attach the body frame to an end effector of a robot arm.

4. The apparatus according to the claim 1, wherein the at least one sensor is optical sensor or mechanical push switch.

5. The apparatus according to the claim 1, wherein the at least one signal is LED.

6. The apparatus according to the claim 1, each of the at least one sensor further comprising:
a sealing lid configured to seal the sensor from an environment in the chamber.

7. An apparatus for detecting object positions in a chamber of a wafer processing system, comprises:
a body frame comprising a sensing part and an indicating part, wherein the sensing part comprises a plurality of sensors for sensing positions of objects in a chamber and the indicating part comprises a plurality of signals for indicating detection of the objects, wherein each of the plurality of sensors connected to each of the plurality of signals respectively and when an object is detected by a first sensor, a first signal connected to the first sensor is configured to be lit to show the location of that detection,
a processor disposed inside of the body frame and connected to each of the plurality of sensors, and configured to compute the locations of sensed objects in the chamber, and
a power unit disposed in the body frame and configured to supply power to the plurality of signals.

8. The apparatus according to claim 7, the body frame further comprising:
a linking part configured to connect the sensing part and the indicating part.

9. The apparatus according to the claim 7, the body frame further comprising:
at least one concave groove line disposed on one side of the body frame and configured to attach the body frame to an end effector of a robot arm.

10. The apparatus according to the claim 7, wherein the plurality of sensors is one of the optical sensor or mechanical push switch, and wherein the plurality of signals is LED.

11. The apparatus according to the claim 7, each of the plurality of sensors further comprising:
a sealing lid configured to seal the sensor from an environment in the chamber.

12. An apparatus for detecting object positions in a chamber of a wafer processing system, comprises:
a body frame comprising a sensing part and an indicating part, wherein the sensing part comprises a plurality of sensors for sensing positions of objects in a chamber and the indicating part comprises a plurality of signals for indicating detection of the objects, wherein each of the plurality of sensors connected to each of the plurality of signals respectively and when an object is detected by a first sensor, a first signal connected to the first sensor is configured to be lit to show the location of that detection;
a communication unit disposed inside of the body frame and connected to the plurality of sensors, the communication unit configured to send out location information of the sensed objects, and
a power unit disposed in the body frame and configured to supply power to the plurality of signals.

13. The apparatus according to the claim 12, further comprising:
a processor disposed inside of the body frame and connected to each of the plurality of sensors and configured to compute the locations of sensed objects in the chamber.

14. The apparatus according to the claim 12, the body frame further comprising:
a linking part configured to connect the sensing part and the indicating part.

15. The apparatus according to the claim 12, the body frame further comprising:
at least one concave groove line disposed on lower side of the body frame and configured to attach the body frame to an end effector of a robot arm.

16. The apparatus according to the claim 12, wherein the plurality of sensors is one of optical sensor or mechanical push switch.

17. The apparatus according to the claim 12, wherein the plurality of signals is LED.

18. The apparatus according to the claim 12, each of the plurality of sensors further comprising:
a sealing lid configured to seal the sensor from an environment in the chamber.

19. The apparatus according to the claim 7, the processor further comprises a memory for saving data.
